(19) United States
(12) Patent Application Publication
(10) Pub. No.: US 2013/0329205 A1
(43) Pub. Date: Dec. 12, 2013

(54) MASKLESS LITHOGRAPHY SYSTEM

(71) Applicant: Chin-Feng Wan, Hsinchu City (TW)

(72) Inventor: Chin-Feng Wan, Hsinchu City (TW)

(21) Appl. No.: 13/910,654

(22) Filed: Jun. 5, 2013

(30) Foreign Application Priority Data
Jun. 6, 2012 (TW) 101210891

(51) Int. Cl. G03F 7/20

(52) U.S. Cl. CPC G03F 7/702
USPC 355/67

(57) ABSTRACT

A maskless lithography system includes a light source, a first lens group, a digital micromirror device, a grating device, a second lens, a reflective mirror, and a third lens. The light source provides a light beam. The first lens group is used for guiding the light beam. The digital micromirror device includes plural micromirrors. The optical switching states of the micromirrors are controlled by a controlling device, so that a patterned light beam is outputted from the digital micromirror device. The grating device is used for allowing a portion of the patterned light beam to go through, thereby controlling a light amount. The patterned light beam is guided by the second lens. The reflective mirror may change a path of the patterned light beam. The third lens is used for guiding the patterned light beam to a sample platform, thereby carrying out a photochemical reaction.

### FIELD OF THE INVENTION

The present invention relates to a lithography system, and more particularly to a maskless lithography system.

### BACKGROUND OF THE INVENTION

A biochip is a miniaturized device that allows specific biochemical reactions between specified biological materials (e.g. nucleic acid or protein) and other under-test biological samples by employing Micro Electro Mechanical System. After the reaction signals are quantified by various sensors, the possible biochemical reactions can be realized. In other words, the biochip is a miniaturized device fabricated by a microelectronic technology, a microfluidic technology and a biological technology. The applications of the biochip cover the disease diagnosis, the gene probe, the pharmaceutical technology, the microelectronic technology, the semiconductor technology, the computer technology, and the like.

Generally, the substrate of the biochip is for example a silicon chip substrate, a glass substrate or a polymeric substrate. In addition, by a miniaturizing technology, biological molecules (e.g. nucleic acid or protein) are integrated into the substrate to be served as biological probes in order for detecting or analyzing the biological samples. As known, the biochip has many benefits. For example, the biochip has small volume. Moreover, the biochip enables the researchers to quickly perform parallel analysis on large numbers of biological samples for a variety of purposes such as biological treatment, biological analysis, biological detection, new drug development and environmental monitoring.

Generally, biochips are classified into two types, i.e. a lab-on-a-chip and a microarray biochip. The lab-on-a-chip is a device that integrates one or several laboratory functions on a single chip. The goal of the microarray biochip is to simultaneously acquire large numbers of detection data. Depending on the probe types, the microarray biochips may be divided into two types, i.e. a gene chip and a protein chip. In the microarray biochip, different DNA or protein molecules are closely fixed on an area of several square centimeters at a spacing interval of several hundred micrometers to be served as the biological probes. After under-test biological samples chemically react with the probes of the biochip, the reaction signals may be analyzed by a scanning instrument and an analyzing instrument. Consequently, the researchers can quickly acquire the information about large numbers of gene sequences or protein behaviors in a short time period.

Regardless of the synthesis stages or the detection stages of the biochips, the photochemical reaction plays an important role. In other words, the optical path system of the photochemical reaction is an important subject of the present invention.

### SUMMARY OF THE INVENTION

The present invention provides a maskless lithography system for performing an optical imaging operation according to a predetermined pattern of a digital micromirror device. By guiding a light beam to a sample platform, the position of carrying out the photochemical reaction on the sample platform can be effectively controlled.

In accordance with an aspect of the present invention, there is provided a maskless lithography system for a photochemical reaction. The maskless lithography system includes a light source, a first lens group, a digital micromirror device, a grating device, a second lens, a reflective mirror, and a third lens. The light source is used for providing a light beam. The first lens group is located downstream of an optical path of the light beam for guiding the light beam. The digital micromirror device is located downstream of an optical path of the first lens group, and includes plural micromirrors. Moreover, the optical switching states of the micromirrors are controlled by a controlling device, so that a patterned light beam is outputted from the digital micromirror device. The grating device is located downstream of an optical path of the digital micromirror device for allowing a portion of the patterned light beam to go through, thereby controlling a light amount. The second lens is located downstream of an optical path of the grating device for guiding the patterned light beam. The reflective mirror is located downstream of an optical path of the second lens for changing a path of the patterned light beam. The third lens is located downstream of an optical path of the reflective mirror for guiding the patterned light beam to a sample platform, thereby carrying out the photochemical reaction.

In an embodiment, the light source is a mercury lamp for providing a UV light beam.

In an embodiment, the first lens group includes at least two lenses. Preferably, the first lens group includes three lenses.

In an embodiment, the controlling device is a computer, and the computer has a designed image for controlling a position of the sample platform to carry out the photochemical reaction.

In an embodiment, the grating device further includes an adjustable grating window.

In an embodiment, the third lens is a focusing lens.

In an embodiment, the sample platform is a microscope platform with a chip.

The above contents of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the architecture of a maskless lithography system according to an embodiment of the present invention; and

FIG. 2 schematically illustrates a digital micromirror device used in the maskless lithography system of FIG. 1.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

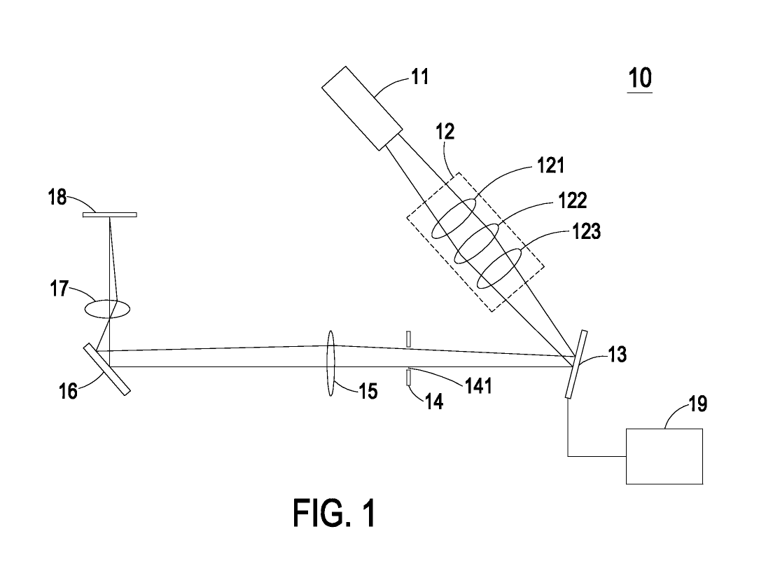

FIG. 1 schematically illustrates the architecture of a maskless lithography system according to an embodiment of the present invention. As shown in FIG. 1, the maskless lithography system 10 comprises a light source 11, a first lens group 12, a digital micromirror device (DMD) 13, a grating device 14, a second lens 15, a reflective mirror 16, and a third lens 17. The maskless lithography system 10 can perform an optical imaging operation according to a predetermined pattern of the digital micromirror device 13. By guiding a light beam to a sample platform 18, the position of carrying out the photochemical reaction on the sample platform 18 can be effectively controlled.

The light source 11 is used for providing a light beam. An example of the light source 11 includes but is not limited to a high pressure mercury lamp. In case that the light source 11 is a high pressure mercury lamp, the light beam is a UV light beam. The first lens group 12 is arranged between the light source 11 and the digital micromirror device 13 for guiding the light beam from the light source 11 to the digital micromirror device 13. Moreover, the first lens group 12 comprises at least two lenses. In this embodiment, the first lens group 12 comprises three lenses 121, 122 and 123. After the curvatures of these lenses are precisely calculated according to the imaging requirements, the efficacy of guiding the light beam is enhanced. In an embodiment, the three lenses 121, 122 and 123 are all plano-convex lenses. Alternatively, in some other embodiments, the three lenses 121, 122 and 123 are all biconvex lenses. Alternatively, in some other embodiments, the three lenses 121, 122 and 123 may be selected from the combination of biconvex lenses and plano-convex lenses.

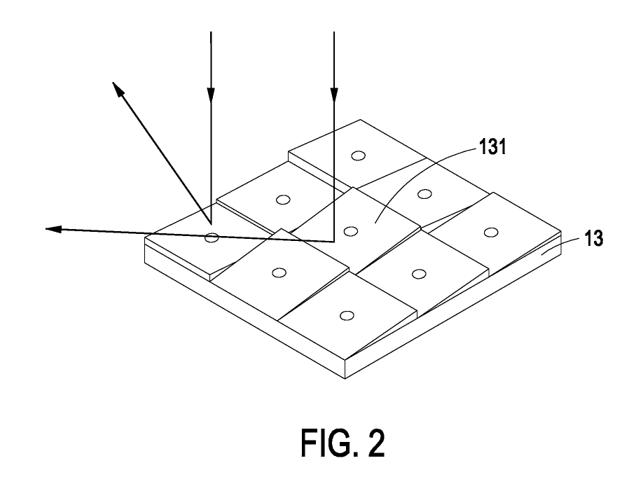

The digital micromirror device 13 comprises plural micromirrors 131 (see FIG. 2). These micromirrors 131 are arranged in an array with a desired size. The optical switching states of the micromirrors 131 are controlled by a controlling device 19, so that a patterned light beam is outputted from the digital micromirror device 13. In an embodiment, the controlling device 19 is a computer for converting a designed image into a control signal and adjusting the orientation of the micromirrors 131, thereby controlling the optical switching states of the micromirrors 131. That is, since the optical switching states of respective micromirrors 131 are controlled by the controlling device 19, the light beam is selectively to be guided to be directed toward the grating device 14 or away from the grating device 14. Since the operations of the plural micromirrors 131 are controlled by the controlling device 19 according to the desired image, the light beam provided by the light source 11 is converted into the patterned light beam, and the patterned light beam is directed to the grating device 14.

The grating device 14 comprises an adjustable grating window 141 for allowing a portion of the patterned light beam to go through. Since the size of the grating window 141 is adjustable, the light amount to be introduced into the grating window 141 can be controlled in order to increase the light contrast and the resolution of the image. Of course, the size of the grating window 141 may be adjusted according to the practical requirements.

After the patterned light beam is transmitted through the grating window 141 of the grating device 14, the patterned light beam is directed to the second lens 15. By the second lens 15, the patterned light beam is guided to the reflective mirror 16. The reflective mirror 16 is used for changing the path of the patterned light beam, so that the patterned light beam is directed in a direction toward the sample platform 18. Then, the patterned light beam is directed to the sample platform 18 through the third lens 17. In an embodiment, the third lens 17 is a focusing lens.

An example of the sample platform 18 includes but is not limited to a microscope platform. In an embodiment, the sample platform 18 further comprises an imaging substrate (e.g. a chip). By the maskless lithography system 10 of the present invention, the position of carrying out the photochemical reaction on the chip can be effectively controlled.

The maskless lithography system of the present invention may be applied to the fabrication of a biochip. For example, for defining a microarray structure in the biochip, it is necessary to form a photoresist pattern layer on a substrate of a chip. Firstly, a photoresist layer (e.g. an epoxy-based photoresist material layer such as a SU-8 photoresist layer) is formed on a surface of the substrate. Then, by using the maskless lithography system of the present invention to irradiate a specified position of the photoresist layer, the photoresist layer is subjected to polymerization. After a developing solution is used to remove the unpolymerized photoresist layer, the photoresist pattern layer is fabricated. Then, biological materials (e.g. nucleic acid or protein) are bonded onto the photoresist pattern layer, so that the biochip is fabricated. Since the photoresist pattern layer is formed by the maskless lithography system of the present invention, it is not necessary to use the conventional costly photomask. Moreover, since the photoresist pattern layer is produced by a maskless lithography process, each spot of the microarray structure has a diameter smaller than 300 μm and the fabricating process is simplified.

Moreover, the maskless lithography system of the present invention may be applied to the synthesis of DNA. After a DNA is irradiated to generate broken bonds and the protective groups at the 5′-end of the nucleotide are removed, the nucleotide molecules (e.g. A, T, C, G) to be linked are subjected to a synthesizing reaction. After the unreacted nucleotide molecules are washed off, the steps of irradiating, adding nucleotide molecules and washing are repeatedly done. Consequently, the DNA with a desired sequence is synthesized. In cooperation of a microfluidic system, the maskless lithography system of the present invention may be used to control the irradiating position and determine the linking position of the nucleotide molecules on the chip in each synthesizing step, so that plural DNA molecules with different sequences may be synthesized on the chip in the same fabricating process. Consequently, a DNA chip for screening disease or detecting biologic molecules is prepared.

From the above descriptions, the present invention provides a maskless lithography system for a photochemical reaction. The maskless lithography system includes a light source, a first lens group, a digital micromirror device, a grating device, a second lens, a reflective mirror, and a third lens. The maskless lithography system is used for performing an optical imaging operation according to a predetermined pattern of a digital micromirror device. By guiding a light beam to a sample platform, the position of carrying out the photochemical reaction on the sample platform can be effectively controlled. The maskless lithography system of the present invention may be applied to the fabrication of a biochip. For example, the maskless lithography system of the present invention may be used to form a photoresist pattern layer on a substrate of a chip or synthesize DNA. In other words, the maskless lithography system of the present invention has industrial applicability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A maskless lithography system for a photochemical reaction, said maskless lithography system comprising:
a light source for providing a light beam;
a first lens group located downstream of an optical path of said light beam for guiding said light beam;
a digital micromirror device located downstream of an optical path of said first lens group, and comprising plural micromirrors, wherein optical switching states of said micromirrors are controlled by a controlling device, so that a patterned light beam is outputted from said digital micromirror device;
a grating device located downstream of an optical path of said digital micromirror device for allowing a portion of said patterned light beam to go through, thereby controlling a light amount;
a second lens located downstream of an optical path of said grating device for guiding said patterned light beam;
a reflective mirror located downstream of an optical path of said second lens for changing a path of said patterned light beam; and
a third lens located downstream of an optical path of said reflective mirror for guiding said patterned light beam to a sample platform, thereby carrying out said photochemical reaction.

2. The maskless lithography system according to claim 1, wherein said light source is a mercury lamp.

3. The maskless lithography system according to claim 1, wherein said light beam provided by said light source is a UV light beam.

4. The maskless lithography system according to claim 1, wherein said first lens group comprises at least two lenses.

5. The maskless lithography system according to claim 1, wherein said first lens group comprises three lenses.

6. The maskless lithography system according to claim 1, wherein said controlling device is a computer, and said computer has a designed image for controlling a position of said sample platform to carry out said photochemical reaction.

7. The maskless lithography system according to claim 1, wherein said grating device further comprises an adjustable grating window.

8. The maskless lithography system according to claim 1, wherein said third lens is a focusing lens.

9. The maskless lithography system according to claim 1, wherein said sample platform is a microscope platform.

10. The maskless lithography system according to claim 1, wherein said sample platform further comprises a chip.
